(19) United States
(12) Patent Application Publication
(10) Pub. No.: US 2025/0313942 A1
(43) Pub. Date: Oct. 9, 2025

(54) AlCrN/TiSiN/AlCrTiSiON pre-oxidized multilayer composite coating and preparation process thereof

(71) Applicant: Tianjin University of Technology and Education, Tianjin (CN)

(72) Inventors: Tiegang Wang, Tianjin (CN); Wuligi Bai, Tianjin (CN); Yanmei Liu, Tianjin (CN); Qi Liu, Tianjin (CN); Qixiang Fan, Tianjin (CN); Fengting Cao, Tianjin (CN)

(73) Assignee: Tianjin University of Technology and Education, Tianjin (CN)

(21) Appl. No.: 19/236,964

(22) Filed: Jun. 12, 2025

(30) Foreign Application Priority Data
Dec. 27, 2024 (CN) 202411954939.1

(51) Int. Cl. C23C 14/32; C23C 14/02; C23C 14/06

(52) U.S. Cl. CPC C23C 14/325; C23C 14/021; C23C 14/0641

(57) ABSTRACT

The invention discloses an AlCrN/TiSiN/AlCrTiSiON pre-oxidation multilayer composite coating and a preparation process thereof, belonging to the technical field of coatings. The bottom layer of the composite coating is an AlCrN transition layer, and an AlCrN/TiSiN nano multilayer film and a TiSiN high-hardness layer are sequentially stacked for 1-4 times on the transition layer; The outermost layer is a compact AlCrTiSiON pre-oxidation coating, wherein the AlCrTiSiON pre-oxidation coating has excellent wear resistance and heat resistance. The coating is prepared by adopting an arc ion plating technology. The invention prepares the pre-oxidation coating with high hardness, high wear resistance and high heat resistance through process design and optimization of coating structure and pre-oxidation layer process parameters.

### TECHNICAL FIELD

This invention relates to the technical field of coatings, in particular to an AlClN/TiSiN/AlCrTiSiON pre-oxidation multilayer composite coating and a preparation process thereof.

### BACKGROUND

Hard coating is a kind of protective layer applied on the surface of cutting tools in order to improve the cutting performance of cutting tools. Selecting appropriate coating composition and structure can effectively improve the mechanical properties and wear resistance of cutting tools, and can provide chemical barrier and thermal barrier. These coatings are usually based on TiN or CrN binary coatings, and have been further developed to Ti(C,N), (Ti,Al)N and other multi-coatings. In recent years, with the rapid development of modern high speed and dry cutting technology, the cutting temperature of cutting tools has also risen, resulting in temperatures which can reach 1200° C. or even higher. Al, Cr, Si, Ti and other elements in coatings will react with O at high temperature, and the Gibbs free energy (ΔGo) of Al₂O₃ and TiO₂ formation is −1336 J and −753 J respectively. Therefore, Al will preferentially diffuse out and form Al₂O₃ films on the surface of coatings. With such increases in temperature, when the surface layer is short of Al, oxygen will diffuse to the inner layer, and porous TiO₂ oxide layer will be formed rapidly in the sublayer. Porous TiO₂ will crack the Al₂O₃ layer due to compressive stress, and accelerate the diffusion of Ti through these cracks, so that a loose and porous mixed (Al, Ti) oxide film will be formed on the surface of the coating. Under the action of high temperature and high pressure, oxides and chips will be extruded and accumulated continuously, resulting in the accumulation of bonding layer, which seriously limits the service performance and life of coated tools at high temperature. Therefore, it is one of the focuses of this disclosure to enlarge the application range of nitride coatings and improve the thermal stability of nitride coatings for cutting tools.

Previous studies have shown that by adjusting the structure, grain size, chemical composition and phase composition of coatings, the thermal stability properties of the coatings can be further optimized on the basis of the original properties of the coatings. Previous studies have shown the effect of different temperatures on the phase structure of nanocomposite TiN/TiB₂ coatings, and it was found that the phase structure of the coatings was in a stable state below 1000° C. While at higher temperatures coating grains start to coarsen, the number of nucleation sites and the interfacial energy decrease, which in turn affects the thermal stability of the coating. Aluminum atoms will replace chromium atoms in AlCrN coatings with high Al content, which affects the grain size of the coating and effectively improves the oxidation resistance of the coating. The effect of different Al contents on TiAlClN coatings was also explored, and it was found that the coatings exhibited excellent mechanical properties and oxidation resistance at high temperatures when the Al and Cr contents were 65˜70 at % and about 20 at %, respectively. Similarly, it was found that different Ti:Al ratios affect the maximum temperature of oxidation resistance, which ranges from 750° C. to 900° C. This is related to the structural composition of the two phases of TiAlN coatings, c-TiN and h-AlN, as well as the larger atomic volume and higher nucleation barrier of h-AIN. Al—Cr—O—N and Zr—O—N tool coatings were prepared by introducing oxygen elements, and it was found that the doping of oxygen elements gave the coatings excellent mechanical and tribological properties required for general hard coatings, and also showed good thermal and chemical stability of oxides, which greatly improved the tool service life and machining efficiency in high-speed cutting of high-strength austempered ductile iron. To add Mo elements to the CrN film, the study of CrMoN coating microstructure and high temperature mechanical properties, the results show that the CrMoN film oxidized at 500° C. for 1 h still maintains the crystal structure and mechanical properties at room temperature. However, as the oxidation temperature increases, the evaporation of MoO₃ on the surface of the film increases, the degree of oxidation of the film increases, and along the emergence of small pores. 700° C. oxidation for 1 h, the mechanical properties of the CrMoN film and the film-based bonding strength decreased significantly. However, summarizing the previous studies, it was found that there are fewer studies to enhance the thermal stability performance of coatings by means of pre-oxidation treatment.

### SUMMARY

Aiming at the problems of high cutting temperature, large cutting force and easy oxidation wear of a cutter in the processing of high strength, high toughness and difficult machining materials such as high temperature alloy and the like existing in the prior art, the invention aims to provide an AlCrN/TiSiN/AlCrTiSiON preoxidation multilayer composite coating and a preparation process thereof. An oxide film with the thickness of 100˜200 nanometers is prepared on the surface of the AlCrN/TiSiN coating by adopting an arc ion plating technology to form an AlCrN/TiSiN/AlCrTiSiON coating, The pre-oxidation coating with high hardness, wear resistance and heat resistance was prepared by process design and optimizing the thickness of oxide film.

In order to achieve the above object, the technical scheme adopted by the present invention is as follows:

An AlCrN/TiSiN/AlCrTiSiON pre-oxidation multilayer composite coating is deposited on the surface of a substrate, wherein the bottommost layer is an AlCrN transition layer, an AlCrN/TiSiN nano multilayer film and a TiSiN high-hardness layer are sequentially stacked on the transition layer for 1-4 times; the outermost layer is an AlCrTiSiON pre-oxidation coating; and the compact AlCrTiSiON pre-oxidation coating has excellent wear resistance and heat resistance.

Further, the AlCrN transition layer has a columnar crystal structure and has good bonding performance with the substrate.

Further, the AlCrN/TiSiN nano multilayer film is a modulated coating formed by alternately depositing AlCrN layers and TiSiN layers. The total thickness of the AlCrN/TiSiN nano multilayer film is 1-3 μm, the periodic thickness is 0.012-0.036 μm, and the modulation ratio AlCrN/TiSiN=3:1˜1:3; the nano multilayer film has good toughness as a functional layer and can effectively reduce crack propagation.

Further, the chemical composition of said AlCrTiSiON pre-oxidized coating is: Al 10.66 to 11.25 wt. %, Cr 10.30 to 10.21 wt. %, Ti 36.93-38.47 wt. %, Si 2.53 to 2.59 wt. %, O 2.45 to 13.45 wt. %, N 24.18 to 26.91 wt. %.

Further, the AlCrTiSiON pre-oxidation coating comprises TiO, AlN, TiN and CrN crystal phases, wherein the TiO crystal phase is mainly composed of a face-centered cubic (fcc) structure.

Further, the preparation process of the AlCrN/TiSiN/AlCrTiSiON pre-oxidation multilayer composite coating comprises the following steps of: firstly depositing an AlCrN/TiSiN nano multilayer film on a substrate by adopting an arc ion plating technology, then depositing a TiSiN high hardness layer, and finally depositing an AlCrTiSiON pre-oxidation coating; when depositing the AlCrTiSiON pre-oxidation coating, the background vacuum degree is more than 6×10⁻⁵ Pa, the deposition temperature is 480-520° C., the AlCr target and the TiSi target are turned on, the arc source current of the AlCr target is 120˜140 A, and the arc source current of the TiSi target is 140˜150 A; N₂ and O₂ are introduced simultaneously, the flow rate of N₂ is 1200˜1300 sccm, the flow rate of O₂ is 20˜50 sccm, and the thickness of pre-oxidation coating is selected according to different experimental requirements.

The process comprises the following steps:
(1) cleaning and drying the substrate, fixing the substrate on a sample plate, hanging the substrate on a rotating rack in a coating chamber, and vacuumizing the substrate until the vacuum degree in the coating chamber is above 3.0×10⁻⁴ Pa;
(2) IET etching and cleaning the substrate;
(3) Depositing an AlClN transition layer; opening an AlCr target and introducing N₂ for 30˜35 min;
(4) Depositing an AlCrN/TiSiN nano multilayer film: alternately turning on an AlCr target and a TiSi target, simultaneously adjusting the flow rate of introduced Na to be 1260˜1380 sccm, and depositing for 20˜25 min to obtain the AlCrN/TiSiN nano multilayer film with AlClN layers and TiSiN layers alternately arranged;
(5) Depositing a TiSiN high-hardness layer: closing the AlCr target, keeping TiSi target open, adjusting N₂ flow rate to 1200˜1260 sccm, depositing time to 30˜35 min;
(6) Repeating the process of steps (4)-(5) for 0-3 times;
(7) Depositing an AlCrTiSiON pre-oxidation coating for 5-20 min, and finally obtaining an AlCrN/TiSiN/AlCrTiSiON pre-oxidation multilayer composite coating on the substrate.

Further, in the step (2), the IET etching cleaning process comprises heating the furnace to 480-520° C., opening the Ti target, introducing Ar with a flow rate of 170˜300 sccm, stabilizing the deposition pressure at 0.28˜0.30 Pa, setting the arc source current of the Ti target at 130˜140 A, gradually increasing the DC bias voltage from −10 V to −180 V, and etching and cleaning the IET for 60 min;

Further, in step (3), after IET etching and cleaning, an AlCrN transition layer is deposited, wherein N₂ with a flow rate of 1200˜1260 sccm is introduced to stabilize the deposition pressure at 3.5˜4.5 Pa, the arc source current of the AlCr target is 120˜140 A, and the DC bias voltage is −40 ˜−60 V.

Further, when depositing the AlClN/TiSiN nano-multilayer film in step (4), the current of the AlCr target arc source is 120 A, the current of the TiSi target arc source is 150 A, the deposition pressure is 3.5˜4 Pa, and the DC bias voltage is −60 V.

Further, when the TiSiN high-hardness layer is deposited in step (5), the arc source current of the TiSi target is 150 A, the deposition pressure is 3.5˜4 Pa, and the DC bias voltage is −60 V.

Further, the substrate is a metal carbide substrate, and the purity of the target material of the AlCr target and the TiSi target is more than 99.95%.

Further, when the AlCrTiSiON pre-oxidation coating is deposited, the oxygen content in the coating is 2.45 wt. % when the oxygen passage time is 5 min; the oxygen content in the coating is 3.48 wt. % when the oxygen passage time is 10 min; the oxygen content in the coating is 8.52 wt. % when the oxygen passage time is 15 min; and the oxygen content in the coating is 13.45 wt. % when the oxygen passage time is 20 min.

The hardness of the AlCrTiSiON pre-oxidation coating is as high as 46.5 GPa, the friction coefficient of the coating is as low as 0.657, and the wear rate of the coating is as low as 3.18×10⁻¹⁰ mm³/(mm·N).

The design mechanism of the invention is as follows:

The present invention uses are ion plating technology to deposit AlClN/TiSiN/AlCrTiSiON coatings on cemented carbide substrates.

Transition metal nitrides are widely used in the field of tool coatings due to their high hardness and high purity. With the application of difficult-to-machine alloy materials such as titanium alloys, tungsten-molybdenum alloys, and high-temperature alloys, cutting forces and cutting temperatures have increased sharply. Higher requirements are put forward for the heat resistance of tools. There are two main reasons for tool failure at high temperatures: 1. If the temperature is too high, the coating softens and the hardness decreases, and the wear increases; 2. The coating is oxidized and corroded at high temperature, and atoms enter the coating interior to cause coating failure. In recent years, metal oxide films have been widely used in the field of high temperature protection due to their excellent heat resistance. For example, dense oxide films such as Al₂O₃ and Cr₂O₃ can effectively block the diffusion of external oxygen elements into the coating and block the diffusion of Ti atoms into the coating. Therefore, by adjusting the thickness of the oxide layer and cooperating with other process parameters (power of each target, bias voltage, pressure, etc.), the invention designs a nano multilayer functional layer in the coating by designing process conditions and optimizing the thickness of the oxide layer to provide sufficient mechanical performance support. An oxide film of 100˜200 nanometers is prepared in the outermost layer to play the role of chemical barrier and thermal barrier.

The advantages and beneficial effects of the present invention are as follows:
1. The AlCrN/TiSiN/AlCrTiSiON coating prepared by the present invention has a high anti-wear capacity and a significant wear-resistant effect.
2. The AlCrN/TiSiN/AlCrTiSiON coating of the present invention maintains the original high hardness and high toughness characteristics of the AlClN/TiSiN coating, and by adding a pre-oxidized protective layer to increase the heat resistant capability of the coating, a pre-oxidized coating with both high hardness, high wear-resistant properties and high heat resistant properties is prepared.
3. The AlCrN/TiSiN/AlCrTiSiON coating of the present invention has a wide range of application prospects and is suitable for a variety of difficult-to-machine materials, dramatically improving cutting efficiency and tool service life.
4. The AlCrN/TiSiN/AlCrTiSiON coating of the present invention has excellent mechanical and tribological properties, and the coated tool can be suitable for heavy-duty continued machining.

### DESCRIPTION OF DRAWINGS

FIG. 1 shows a schematic diagram of the structure of the AlCrN/TiSiN/AlCrTiSiON composite protective coating prepared by arc ion plating technology in Example 1.

FIG. 2 shows the XRD patterns of AlCrN/TiSiN/AlCrTiSiON composite coatings deposited at different oxygen pass times prepared by the arc ion plating technique in Example 1.

FIG. 3 shows the surface morphology of AlCrN/TiSiN/AlCrTiSiON composite coatings deposited at different oxygen pass times prepared by the arc ion plating technique in Example 1; wherein (a) oxygen pass 5 min; (b) oxygen pass 10 min; (c) oxygen pass 15 min; (d) oxygen pass 20 min; (e) elemental composition of the coating surface at oxygen pass 10 min; (f) Enlarged view of the flaking place of the coating surface at 20 min of oxygenation.

FIG. 4 shows the cross-sectional morphology of AlCrN/TiSiN/AlCrTiSiON composite coatings deposited at different oxygen exposure times prepared by the arc ion plating technique in Example 1; wherein (a) oxygen exposure is for 5 min; (b) oxygen exposure is for 10 min; (c) oxygen exposure is for 15 min; and (d) oxygen exposure is for 20 min.

FIG. 5 shows the hardness (HIT) and elastic modulus (EIT) of AlCrN/TiSiN/AlCrTiSiON coatings deposited at different oxygen pass times prepared by arc ion plating technique in Example 1.

FIG. 6 shows H/E and H³/E*² of AlCrN/TiSiN/AlCrTiSiON coatings deposited at different oxygen pass times prepared by arc ion plating technique in Example 1.

FIG. 7 shows the critical load of AlCrN/TiSiN/AlCrTiSiON coatings deposited at different oxygen pass times prepared by arc ion plating technique in Example 1.

FIG. 8 shows the scratch morphology of AlCrN/TiSiN/AlCrTiSiON coatings deposited at different oxygen exposure times prepared by the arc ion plating technique in Example 1.

FIG. 9 shows the coefficient of friction and wear rate of AlCrN/TiSiN/AlCrTiSiON coatings deposited at different oxygen exposure times prepared by the arc ion plating technology of Example 1.

FIG. 10 shows the three-dimensional abrasion patterns of AlCrN/TiSiN/AlCrTiSiON coatings deposited under different oxygen exposure times prepared by the arc ion plating technology of Example 1; where (a) oxygen exposure for 5 min; (b) oxygen exposure for 10 min; (c) oxygen exposure for 15 min; and (d) oxygen exposure for 20 min.

### DETAILED DESCRIPTION

The present invention will be described in further detail below by way of examples.

The present invention adopts the method of “coating+pre-oxidation” to form a stable and dense protective oxide layer on the coating surface in situ, preventing the diffusion of harmful elements, reducing the transmission of cutting heat to the tool, enhancing the temperature-resistant oxidation performance and thermal stability of the coating, and thus improving the oxidation and diffusion wear resistance of the tool coating to improve tool life and machining efficiency. This improves the tool coating's ability to resist oxidative wear and diffusive wear and improves the tool's service life and machining efficiency.

In the following embodiments, Al:Cr=70:30 (atomic ratio) in the AlCr target and Ti:Si=85:15 (atomic ratio) in the TiSi target, both with a purity of 99.95%.

### Embodiment 1

This example is for the preparation of AlCrN/TiSiN/AlCrTiSiON composite coatings with different oxygen passage times.

In this embodiment, an AlCrN/TiSiN/AlCrTiSiON coating is deposited on a cemented carbide sheet (25 mm×25 mm×3.0 mm), which is coated by arc ion plating technology. The specific operation steps are as follows:
(1) Substrate pre-treatment: After the carbide substrate is polished and processed, it is placed in an ultrasonic cleaner and ultrasonically cleaned for 20 min in acetone and alcohol, respectively, and blown dry with high-purity N₂ (99.99%) at the end of cleaning. The substrate is fixed in the sample plate, after the vacuum chamber is drained, open the door of the vacuum chamber, fix the sample plate on the rotating frame inside the coating chamber with wire, and install the AlCr target and TiSi target to the arc target position; adjust the fixed position of the sample plate, so that the substrate is directly on the surface of the target material, to prevent the deposition process of the surface of the deposition of the surface of the different distances, resulting in non-uniformity of the phenomenon of the preparation of the coating. Check that there is no foreign matter left inside the vacuum chamber, close the door of the furnace.
(2) Vacuum pumping: In the deposition of the coating requires high vacuum conditions, the vacuuming process of the coating system is divided into two steps: a) rough pumping, open the pre-pumping pump and the Roots pump to vacuum the vacuum of the vacuum chamber to more than 40 Pa; b) fine pumping, open the turbo molecular pump to vacuum the vacuum of the vacuum chamber to more than 3×10⁻⁴ Pa.
(3) Heating: set the heating temperature to 500° C., heating to the specified temperature insulation for 30 min.
(4) IET etching and cleaning: argon ion etching and metal ion etching (Ti) at the same time, the active components of the plasma include: ions, electrons, active groups, excited state of the nuclides (substable), photons and so on. Utilizing the nature of these active components, the fine particles continuously accelerate the bombardment of the material surface, so as to achieve the purpose of enhancing the material surface cleanliness and stimulating the material surface activity. In this example, when IET etching and cleaning, the Ar flow rate is 175 sccm, the deposition pressure is 0.29 Pa, the Ti target arc source current is 130 A, the DC bias voltage is gradually increased from −10 V to −150 V, and the etching and cleaning time is 60 min.
(5) AlCrN transition layer: open the AlCr target, through the N₂ flow rate of 1200 sccm, so that the deposition pressure is stabilized at 0.30 Pa, AlCr target arc source current of 120 A, DC bias voltage −40 V, deposition for 30 min.
(6) Deposition of AlCrN/TiSiN nano-multilayer film: turn on the AlCr target and TiSi target alternately, the arc source current of the AlCr target is 120 A, and the arc source current of the TiSi target is 150 A. Adjust the N2 flow rate of 1320 sccm to stabilize the deposition pressure at 3.6 Pa, DC bias voltage of −60 V, and deposition for 20 min.
(7) Deposit TiSiN high hard layer: close the AlCr target, keep the TiSi target open, TiSi target arc source current is 150 A; adjust the N₂ flow rate to 1200 sccm, deposition pressure 3.5 Pa, DC bias voltage −60 V, deposition time is 30 min.
(8) Repeat steps (6)-(7) once.
(9) Deposition of AlCrTiSiON pre-oxidized coating: AlCr target and TiSi target were turned on at the same time, vacuum was pumped to reach a vacuum of 6×10⁻⁵ Pa or less, the arc source current was 120 A and 150 A. Adjustment of the N₂ flow rate of 1234 sccm, the flow rate of oxygen was 25 sccm, the deposition pressure was 3.5 Pa, DC bias voltage was −50 V. The oxygenation times for different samples were 0 min (nitrogen only for 10 min without oxygen), 5 min (nitrogen and oxygen at the same time for 5 min), 10 min (nitrogen and oxygen at the same time for 10 min), 15 min (nitrogen and oxygen at the same time for 15 min), and 20 min (nitrogen and oxygen at the same time for 20 min), respectively.
(9) The AlCrN/TiSiN/AlCrTiSiON coatings prepared in this embodiment with different oxygen passage times were subjected to morphological characterization and performance testing as follows:

X-ray diffractometer (XRD) was used to analyze the physical composition of the coatings, and the data were collected by step scanning method, and the incident X-rays were selected to be radiated from the Kα characteristic spectral line of the Cu target (λ=0.154056 nm), with a tube voltage of 40 kV, a tube current of 40 mA, a diffraction angle (2θ) of the scanning range of 20° to 80°, a scanning step length of 0.02°, and a counting time of 0.2 s for each step. A field emission scanning electron microscope (SEM) model S4800 was used to observe the surface and cross-section morphology, and the coating chemical composition was observed with an electron probe (EPMA, Shimadzu, EPMA). The surface and cross-section morphology of the coatings were observed by a field emission scanning electron microscope (SEM) model S4800, and the chemical composition of the coatings was analyzed using an electron microprobe (EPMA, Shimadzu, EPMA 1600).

The hardness and modulus of elasticity of the coatings were tested using a nanoindentation tester (Anton Paar, TTX-NHT-3). In order to eliminate the influence of matrix effects on the measurement results, the indentation depth of the tip of the needle was ensured to be no more than 1/10 of the coating thickness, and an average value was taken for the measurement of 15 points. A scratch tester (Anton Paar RST-3) was used to measure the bonding strength between the coating and the cemented carbide substrate, with a diamond tip diameter of 200 μm, and the following parameters: loading speed of 6 mm/min; scratch length of 3 mm; set load of 100 N. The experimental data were recorded by a computer in real time.

The coefficient of friction was tested on a friction and wear tester (Anton Paar THT). 6 mm diameter Al₂O₃ balls (hardness 22±1 GPa) were used for the friction pair, with a sliding linear velocity of 0.1 m/s, a normal load of 4 N, a rotational radius of 6 mm, and a sliding distance of 100 m. Friction experiments were carried out at a room temperature of 22±3° C. and a humidity of 30%, and each sample was tested three times. The coating wear rate W was calculated using the formula W=V/(F×S) (V is the wear volume, F is the normal load, and S is the sliding distance), and the morphology of the coatings after wear was observed using a super depth-of-field microscope (VHX-1000 C, Keyence).

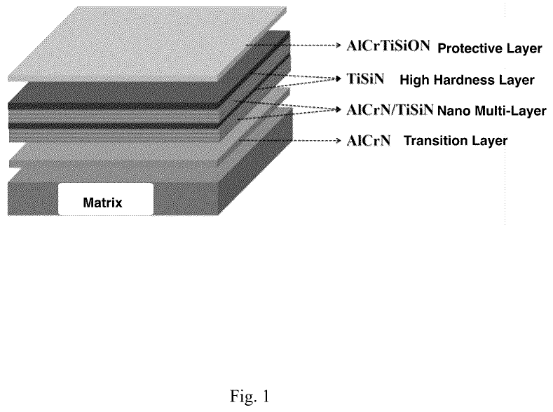

The structure of the AlCrN/TiSiN/AlCrTiSiON composite coating prepared in this embodiment is shown in FIG. 1. The bottom layer of the coating is an AlClN transition layer, and the columnar crystal structure of AlClN has good bonding properties with the cemented carbide matrix. On the transition layer is AlCrN/TiSiN nano-multilayer film, which is a modulation coating formed by alternating deposition of AlCrN layer and TiSiN layer, the total thickness of the nano-multilayer film is about 2 μm, and the cycle thickness is about 0.024 μm, with the modulation ratio of AlCrN/TiSiN=3:1˜1:3; the nano-multilayer film as a functional layer has a good toughness, and it can effectively reduce the crack extension. The nano-multilayer film above the TiSiN high hardness layer, the high hardness layer in the amorphous parcel nanocrystalline structure can enhance the hardness; in this embodiment, the above nano-multilayer film and the high hardness layer repeat a cycle to meet the requirements of the thickness of the coating; the outermost layer of the AlCrTiSiON pre-oxidized coatings, the dense surface oxide film can enhance the wear resistance and heat resistance of the coating.

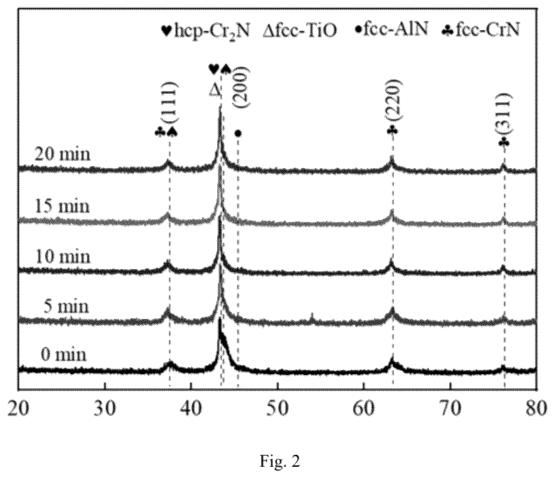

FIG. 2 shows the XRD patterns of AlCrN/TiSiN/AlCrTiSiON coatings deposited at different oxygen pass times. As can be seen from the figure, the AlCrN/TiSiN/AlCrTiSiON coatings are mainly composed of TiO, AlN, TiN and CrN crystalline phases. Among them, the TiO crystalline phase mainly consists of face-centered cubic (fcc) structure. The fcc-TiO (PDF #89-5010) phase diffraction peak was detected at 2θ=43.27°, but no TiO₂ diffraction peak was detected, which may be attributed to the coating deposition temperature of 500° C., where TiO is more easily formed. Since no silicon nitrogen oxide peaks were detected, it may exist as amorphous silicon nitrogen oxide. In the AlCrN/TiSiN/AlCrTiSiON coatings, the silicon exists mostly as amorphous Si₃N₄ to form a nanocomposite coating structure, and when oxygen is passed during the deposition process, due to ΔH(SiO₂)=−910.86 KJ/mol is higher than ΔH(Si₃N₄)=−760.00 KJ/mol is higher, silicon is more likely to react with oxygen first to form SiO₂.

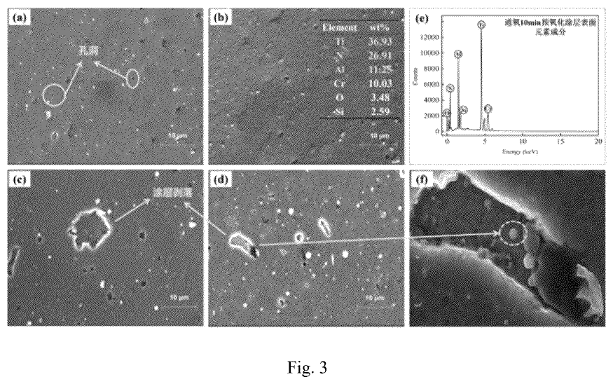

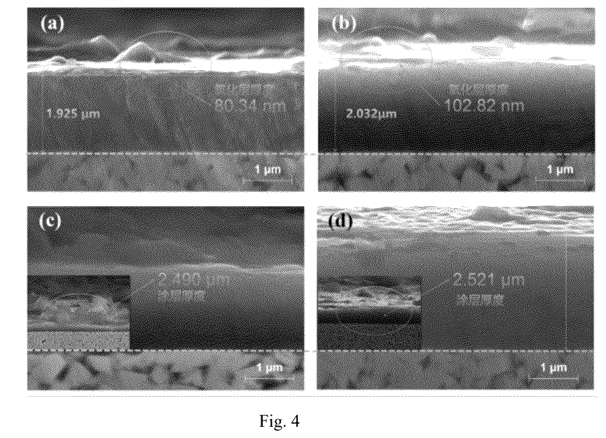

FIG. 3 shows the surface morphology of AlCrN/TiSiN/AlCrTiSiON coatings deposited at different oxygen pass times. With the increase of oxygen pass time, the coating surface changes significantly. When the oxygen time is 5 min, there are irregularly shaped pits and pores on the surface of the coating, and when the oxygen time is 10 min, the surface of the coating is uniform and dense, and the defects such as large particles and pores are significantly improved, which is due to the fact that the oxygen time is relatively short, unable to form a continuous and dense oxidized layer, and the oxidized layer thickness is only 80 nm or so, which is not able to fill up the original defects of the coating. When the oxygen time is increased to 10 min, the surface densification of the coating is significantly improved, showing obvious crystal structure, which is a unique surface structure characteristic of the oxygen time of 10 min compared with other oxygen time coatings, indicating that the oxide film formed by this oxygen time has a better bonding performance with the lower layer of AlCrN/TiSiN coating and the thickness of the oxide film is suitable. By analyzing the elemental composition and stoichiometric ratio of the coating surface at this time, it can be determined that the surface of the coating at this time is mainly composed of metal oxides such as TiO₂, Al₂O₃, Cr₂O₃, etc; when the oxygenation time is 15 min, the surface particles are refined, and the densification is further improved, which is an inherent feature of the oxide coating. However, the defects on the surface of the coating increased, and larger holes and coating spalling appeared. Observation of the enlarged picture of the coating surface spalling at 20 min of oxygenation, it can be found that there are bright white particles at the spalling place, which is formed during the deposition process of the target material evaporation of the molten droplets solidified on the surface of the coating. This indicates that the coating is a large piece of spalling occurring in the process of deposition, and at the deposition of coating temperature of 500° C., the over-thickness of the oxide layer at high temperature due to the role of the coating of the internal stresses is causing the occurrence of brittle spalling.

FIG. 4 shows the cross-sectional morphology of AlCrN/TiSiN/AlCrTiSiON coatings deposited under different oxygenation times. It can be clearly observed that when the oxygen time is 5 min and 10 min, the coating structure is complete, the thickness is uniform and the nanoscale oxide layer structure and thickness can be clearly observed, the thickness of the oxide layer is 80.34 nm and 102.82 nm, respectively, whereas when the oxygen time is 15 min and 20 min, the cross-section of the coating does not have obvious characteristic structure, the undulation fluctuates greatly and the thickness is not uniform. The thickness of the oxide layer could not be judged because of the partial flaking of the oxide layer. In addition, the AlCrN/TiSiN multilayer structure and nanomultilayer structure were designed inside the coating, but no obvious interface and delamination phenomenon were observed, which was attributed to the universal magnetic field system and arc source technology of the multi-arc ion plating equipment, which resulted in a tight bonding of the coating layers and a high coating densification.

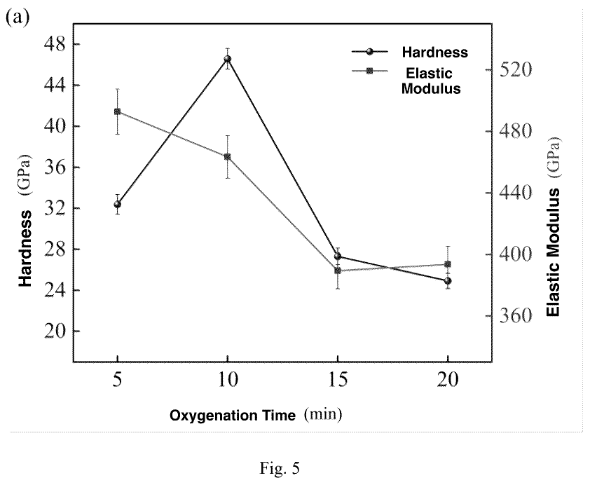

FIG. 5 shows the hardness (HIT) and elastic modulus (EIT) of AlCrN/TiSiN/AlCrTiSiON coatings deposited at different oxygen pass times. The hardness of the coatings showed a tendency of increasing and then decreasing at different oxygenation times. The maximum value of 46.58 GPa was reached at 10 min, which was attributed to the formation of dense hard oxide films such as Al₂O₃ and Cr₂O₃ on the surface of the coatings, and the hard oxide phase enhanced the ability of the coatings to resist the external loads pressed into the surface. However, the hardness and modulus of elasticity of the coating decreased dramatically when the oxygenation time was increased, and the hardness was only 24.91 GPa at 20 min. When the oxide film is too thick, the cubic lattice in the coating produces vacancy defects, which cause the coating nanohardness and modulus of elasticity to decrease. In addition. The oxide is more brittle, especially when the thickness increases, so the ability of the coating to resist elastic deformation decreases with the increase of oxygenation time.

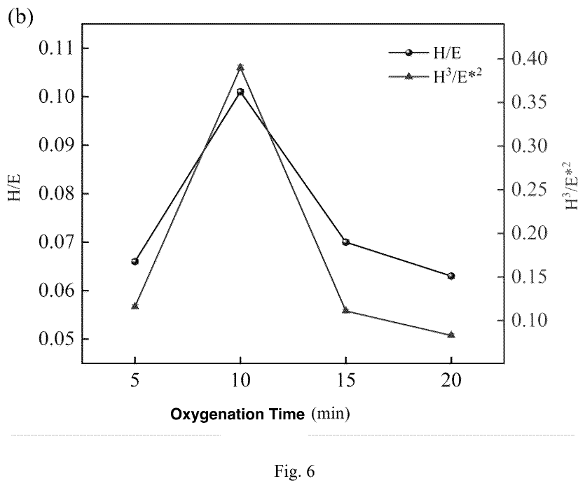

FIG. 6 shows the H/E and H³/E*² of AlCrN/TiSiN/AlCrTiSiON coatings deposited under different oxygen passage times. The ratio of H to E represents the ability of the coating to resist plastic deformation; the higher the ratio of hardness to elastic modulus, the better the abrasion resistance of the coating, and the ratio of H³ to E*² represents the ability of the coating to resist plastic deformation. With the increase of oxygenation time, the characteristic values of AlCrN/TiSiN/AlCrTiSiON multilayer coatings show a tendency of increasing and then decreasing, and reach the maximum value of 0.101 and 0.390 GPa at 10 min of oxygenation time, respectively, indicating that the coatings have good toughness at 10 min of oxygenation.

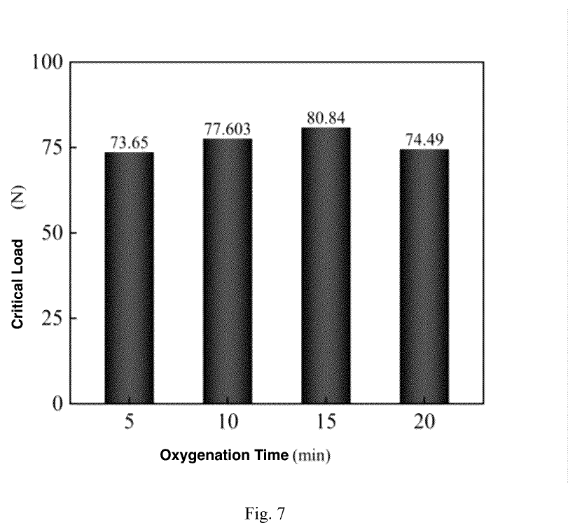

FIG. 7 shows the critical loads of AlCrN/TiSiN/AlCrTiSiON coatings deposited under different oxygen pass times. As can be seen from the figure, the critical load of the coatings under different time of oxygen passage did not produce obvious differences, and all of them reached more than 70 N. According to the machinery industry standard JB/T 8554-1997, the critical load Lc3 when the coating is completely scratched and exposed to the substrate is used as the basis for judgment. Oxygen time is relatively short, the thickness of the oxide layer is only 100 to 200 nm, the overall thickness of the coating is about 2 μm, so the critical load of the coating and the substrate is mainly dependent on the bonding properties of the transition layer and the substrate, and on the other hand, it also indicates that the opening target at the same time as the passage of oxygen, the formation of a thin layer of oxide film on the surface of the coating, the oxygen element does not enter the coating interior, damaging the structure and performance of the coating.

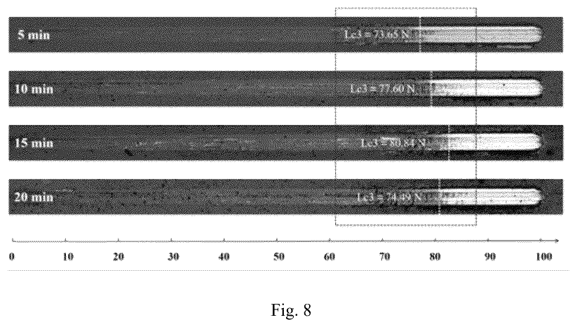

FIG. 8 shows the scratch morphology of AlCrN/TiSiN/AlCrTiSiON coatings deposited at different oxygen pass times. Observation of the scratch morphology also reveals that the scratch morphology at the critical load Lc3 of the coating is very different at different oxygenation times. When the oxygen is applied for 5 min and 10 min, both sides of the scratches are more complete, and the surface of the scratches is smooth with no abrasive buildup. At 10 min and 20 min of oxygenation, brittle spalling occurs on both sides of the scratch, and the coating at the scratch is plastically sheared and slipped. At this time, the toughness of the coating is low, and the coating appears to be cracked under a larger load, and with the increase of load, the hard oxide debris is involved in the scratch, leading to shell-shaped cracks and plastic deformation on the scratch surface. Therefore, it can be judged that the oxide film is too thick to have a negative effect on the coating bonding.

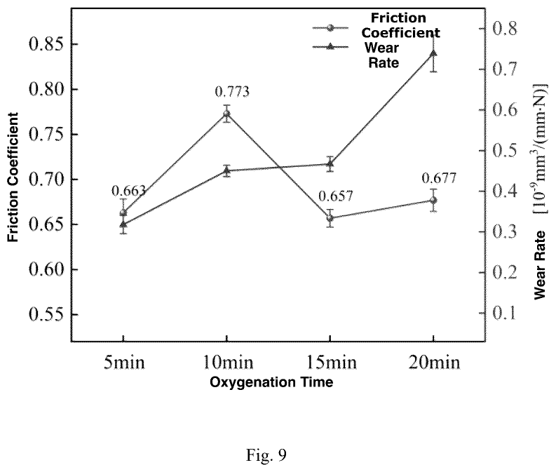

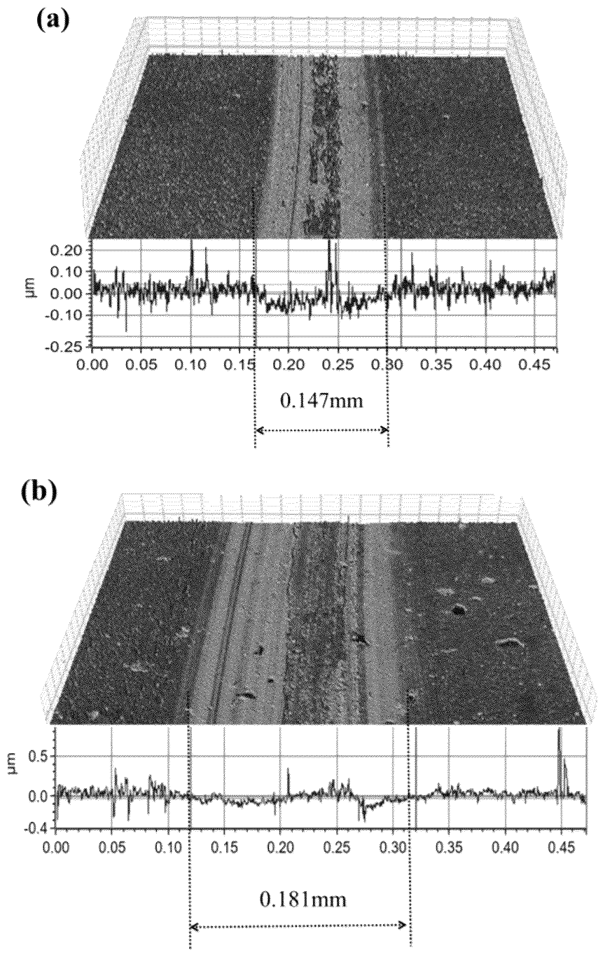

FIG. 9 shows the friction coefficient and wear rate of AlCrN/TiSiN/AlCrTiSiON coatings deposited at different oxygen exposure times. The friction coefficients of the coatings showed a tendency of increasing and then decreasing with the increase of the oxygen exposure time, and the average friction coefficient of the coatings was the lowest at 15 min, which was 0.657. The wear rate of the coatings showed a tendency of increasing with different oxygen exposure times, but it was still lower than that of the AlCrN/TiSiN coatings before pre-oxidization, which proved that the preparation method of “Coating+Pre-oxidization” was suitable for improving the wear resistance performance. This proves that the preparation method of “coating+preoxidation” has significant advantages for improving the wear resistance.

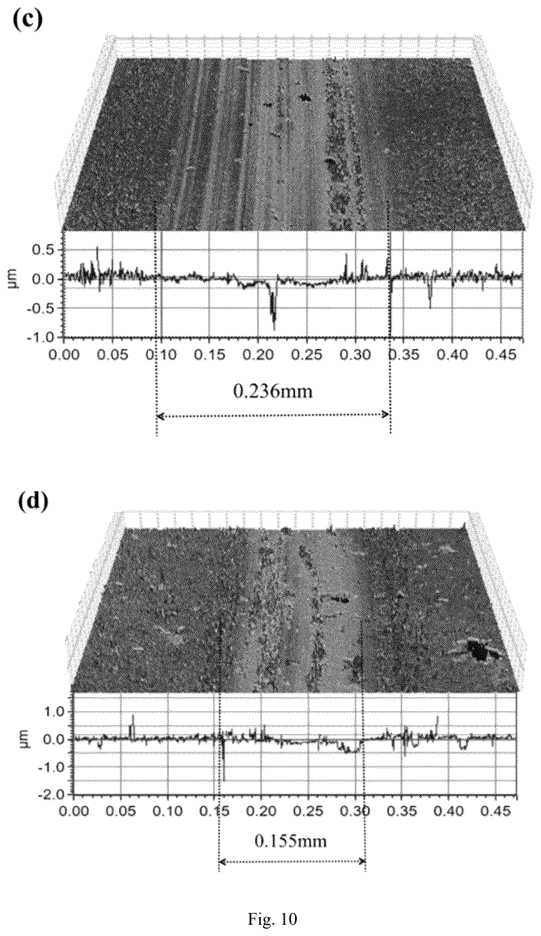

FIG. 10 shows the three-dimensional abrasion patterns of AlCrN/TiSiN/AlCrTiSiON coatings deposited at different oxygen pass times. It is observed that the coatings are all completely abraded, the depth of the abrasion marks is around 0.5 μm, and the two sides of the abrasion marks are more complete. At 10 min of oxygenation, there were micro furrows along the friction direction, with obvious abrasive wear characteristics. Continuing to increase the oxygenation time, the width of the abrasion mark increases and there is more abrasive debris accumulation at the abrasion mark. Therefore, it can be initially judged that the coating wear mechanism is adhesive wear, the change of this wear mechanism is closely related to the hardness and surface quality of the coating. When the oxygen is passed for 10 min, the coating hardness is the highest, the friction wear process, the hard oxide particles on the surface of the coating are involved in the friction process to form a micro-plow groove, whereas at 15 min or 20 min, when the coating hardness is low and the surface quality is poor, the abrasive debris is involved in the friction process by the friction process. The abrasive chips are crushed and adhered to the friction area, in addition, with the increase of oxygenation time, the porous and brittle TiO₂ on the coating surface grows rapidly, and the thickness of the oxide film increases the residual stress inside the coating deteriorates the protective layer of Al₂O₃, which reduces the wear resistance of the coating.

The above exemplary description of the present invention should make it clear that, without departing from the core of the present invention, any simple deformations, modifications, or other equivalent substitutions that are capable of being made by a person skilled in the art without expending creative labor fall within the scope of protection of the present invention.

1. An AlCrN/TiSiN/AlCrTiSiON pre-oxidation multilayer composite coating, characterized in that: the multilayer composite coating is deposited on the surface of a substrate, wherein: a bottom layer is an AlCrN transition layer, the transition layer is sequentially stacked upon by an AlCrN/TiSiN nano multilayer film and a TiSiN high hardness layer for 1-4 times; and the outermost layer is an AlCrTiSiON pre-oxidation coating, wherein the AlCrTiSiON pre-oxidation coating has excellent wear resistance and heat resistance.

2. The AlCrN/TiSiN/AlCrTiSiON pre-oxidation multilayer composite coating according to claim 1, characterized in that the AlCrN transition layer has a columnar crystal structure and has good bonding performance with the substrate.

3. The AlCrN/TiSiN/AlCrTiSiON pre-oxidation multilayer composite coating according to claim 1, characterized in that: the AlCrN/TiSiN nano multilayer film is a modulated coating formed by alternately depositing AlClN layers and TiSiN layers, wherein the total thickness of the AlCrN/TiSiN nano multilayer film is 1-3 μm, the periodic thickness is 0.012-0.036 μm, and the modulation ratio AlCrN/TiSiN is 3:1˜1:3; and wherein the nano multilayer film has good toughness as a functional layer and can effectively reduce crack propagation.

4. The AlCrN/TiSiN/AlCrTiSiON pre-oxidation multilayer composite coating according to claim 1, wherein the chemical composition of the AlCrTiSiON pre-oxidation coating is: Al is 10.66˜11.25 wt. %, Cr is 10.30˜10.21 wt. %, Ti is 36.93˜38.47 wt. %, Si is 2.53˜2.59 wt. %, O is 2.45˜13.45 wt. %, and N is 24.18˜26.91 wt. %.

5. The AlCrN/TiSiN/AlCrTiSiON pre-oxidation multilayer composite coating according to claim 1, characterized in that the AlCrTiSiON pre-oxidation coating comprises TiO, AlN, TiN and CrN crystal phases, wherein the TiO crystal phase is mainly composed of face-centered cubic (fcc) structure.

6. A method of preparing an AlCrN/TiSiN/AlCrTiSiON pre-oxidation multilayer composite coating according to claim 1, characterized in that: the process comprises the following steps: firstly depositing an AlCrN/TiSiN nano multilayer film on a substrate by adopting arc ion plating technology, then depositing a TiSiN high hardness layer, and finally depositing an AlCrTiSiON pre-oxidation coating; wherein, when the AlCrTiSiON preoxidation coating is deposited, the background vacuum is above 6×10⁻⁵ Pa, the deposition temperature is 480-520° C., the arc source current of AlCr target and TiSi target is 120˜140 A and 140˜150 A respectively; N₂ and O₂ are introduced simultaneously, the flow rate of N₂ is 1200˜1300 sccm, the flow rate of O₂ is 20˜50 sccm, and the thickness of pre-oxidation coating can be selected according to different experimental requirements.

7. The method of preparing an AlCrN/TiSiN/AlCrTiSiON pre-oxidation multilayer composite coating according to claim 6, characterized in that the process specifically comprises the following steps:
(1) Cleaning and drying the substrate, fixing the substrate on a sample plate, hanging the substrate on a rotating rack in a coating chamber, and subjecting the substrate to vacuum conditions until the background vacuum in the coating chamber is above 3.0×10⁻⁴ Pa;
(2) IET etching and cleaning the substrate;
(3) Depositing the AlCrN transition layer by opening an AlCr target and introducing N₂, wherein depositing time is 30˜35 min;
(4) Depositing the AlCrN/TiSiN nano-multilayer film by turning on AlCr target and TiSi target alternately, adjusting N₂ flow rate to 1260˜1380 sccm, and depositing for 20˜25 min to obtain the AlCrN/TiSiN nano-multilayer film with AlCrN layers and TiSiN layers alternately arranged;
(5) Depositing the TiSiN hardness layer by closing AlCr target, keeping TiSi target open, adjusting N₂ flow rate to 1200˜1260 sccm, and depositing for 30˜35 min;
(6) Repeating the process of steps (4)-(5) for 0-3 times;
(7) Depositing an AlCrTiSiON pre-oxidation coating for 5-20 min, thus obtaining an AlCrN/TiSiN/AlCrTiSiON pre-oxidation multilayer composite coating on the substrate.

8. The method of preparing an AlCrN/TiSiN/AlCrTiSiON pre-oxidation multilayer composite coating according to claim 7, characterized in that in step (2), the IET etching cleaning process comprises: heating the furnace to 480-520° C., opening a Ti target, introducing Ar with flow rate of 170˜300 sccm, stabilizing deposition pressure at 0.28˜0.30 Pa, setting an arc source current of the Ti target at 130˜140 A, gradually increasing DC bias voltage from −10 V to −180 V, and etching and cleaning by IET for 60 min;
In step (3), depositing the AlCrN transition layer after IET etching and cleaning comprises, introducing N₂ with flow rate of 1200˜1260 sccm to stabilize deposition pressure at 3.5˜4.5 Pa, wherein an arc source current of AlCr target is 120˜140 A, and a DC bias voltage is −40˜−60 V.
In step (4), depositing the AlCrN/TiSiN nano multilayer film comprises, setting an arc source current of the AlCr target to 120 A, wherein an arc source current of the TiSi target is 150 A, deposition pressure is 3.5˜4 Pa, and DC bias voltage is −60 V.
In step (5), depositing the TiSiN high-hardness layer comprises, setting an source current of the TiSi target to 150 A, wherein deposition pressure is 3.5˜4 Pa, and DC bias voltage is −60 V.

9. The method of preparing an AlCrN/TiSiN/AlCrTiSiON pre-oxidation multilayer composite coating according to claim 7, characterized in that: the substrate is a metal cemented carbide substrate; and the target purity of the AlCr target and TiSi target is above 99.95%.

10. The method of preparing an AlCrN/TiSiN/AlCrTiSiON pre-oxidation multilayer composite coating according to claim 7, characterized in that: when depositing the AlCrTiSiON pre-oxidation coating, an oxygen supply time of 5 min yields an O content in the coating of 2.45 wt. %; an oxygen supply time of 10 min, yields an O content in the coating of 3.48 wt. %; an oxygen supply time of 15 min yields an O content in the coating of 8.52 wt. %; and an oxygen supply time of 20 min, yields an O content in coating of 13.45 wt. %.
